(19) United States
(12) Patent Application Publication
(10) Pub. No.: US 2025/0370440 A1
(43) Pub. Date: Dec. 4, 2025

(54) IMPROVED SYSTEMS, METHODS, AND COMPUTER PROGRAM PRODUCTS FOR ENHANCING PRODUCTION WHICH INVOLVES MATERIAL FLOW

(71) Applicant: CODIQ 4.0 LTD, Caesarea (IL)

(72) Inventors: Javier Bruno FARKAS, Nahariyya (IL); Igal LEBEDEV, Beit Yehoshua (IL); Oleg KANDILIYOV, Harish (IL)

(73) Assignee: CODIQ 4.0 LTD, Caesarea (IL)

(21) Appl. No.: 18/876,877

(22) PCT Filed: Jun. 22, 2023
(86) PCT No.: PCT/IL2023/050650

§ 371 Date: Dec. 19, 2024

Related U.S. Application Data
(60) Provisional application No. 63/354,430, filed on Jun. 22, 2022.

(51) Int. Cl. G05B 19/418; G06V 10/20; G06V 10/764

(52) U.S. Cl. CPC G05B 19/41865; G06V 10/255; G06V 10/764

(57) ABSTRACT

System, product or method for facilitating manufacturing in a factory, comprising receiving a P&ID diagram of equipment elements and control modules in the factory and/or using a hardware processor to identify, and to provide an output indication of, material flow routes that connect at least some of the equipment elements and/or control modules including, e.g. for each route, an ordered sequence of equipment elements and/or control modules from a source to a destination and a direction.

### REFERENCE TO CO-PENDING APPLICATIONS

Priority is claimed from U.S. Provisional Patent Application No. 63/354,430 entitled “Improved Systems, Methods And Computer Program Products For Automation Of Plc Code Programming And HMI” and filed Jun. 22, 2022, the disclosure of which application/s is hereby incorporated by reference.

### FIELD OF THIS DISCLOSURE

The present invention relates generally to manufacturing process engineering, and more particularly to systems and methods for process manufacturing.

### BACKGROUND FOR THIS DISCLOSURE

Conventionally, piping & instrumentation diagrams are either hand-drawn or created using suitable software such as E-Draw Max, Lucid, Smart Draw, or Visual Paradigm. A simple P&ID (piping and instrumentation diagram) define diagram is shown here: https://www.edrawsoft.com/templates/pdf/producing-pid.pdf.

RockwellAutomation.com provides “Programming tools and advanced software applications (which) include remote access and data analysis to accelerate development and improve efficiency”. Allen-Bradley is a tradename for automated components and integrated control systems for safety, sensing, industrial control, power control, and motion control. FactoryTalk refers to software that supports an ecosystem of advanced industrial applications including IoT, system design, operations, plant maintenance, and analytics.

US2012004157 to Jones (https://patents.google.com/patent/US20120041570A1/en?oq=US+9417626+(JONES+BRYAN) describes process control configuration with a user interface for developing control strategies of a process plant.

Published U.S. Ser. No. 17/283,676 to Javier Bruno Farkas (publication no. US 2021/0382450) describes computerized programing of a controller of an industrial system.

ISA-88 is a standard addressing batch process control which describes equipment and procedures.

Recursive path computation is known e.g., as described here: https://medium.com/omarelgabrys-blog/path-finding-algorithms-f65a8902eb40?

Searching a graph e.g. breadth first or depth first, is known, e.g. as described here (for bfs—breadth first): https://www.geeksforgeeks.org/breadth-first-search-or-bfs-for-a-graph/.

Graphs which represent connectivity of nodes are known e.g., in the field of graph theory. Existing “Industrial Network Protocols” include SCADA and fieldbus, which describe a flow of information (data) between controllers/computers/IOT, but not a physical flow of physical materials between physical containers.

The disclosures of all publications and patent documents mentioned in the specification, and of the publications and patent documents cited therein directly or indirectly, are hereby incorporated by reference other than subject matter disclaimers or disavowals. If the incorporated material is inconsistent with the express disclosure herein, the interpretation is that the express disclosure herein describes certain embodiments, whereas the incorporated material describes other embodiments. Definition/s within the incorporated material may be regarded as one possible definition for the term/s in question.

### SUMMARY OF CERTAIN EMBODIMENTS

Certain embodiments of the present invention seek to provide a system configured to identify material flow routes automatically.

It is appreciated that each time a route from source A to destination B stops working because some valve or pipe along the route does not work, end-user can use methods herein to generate all routes from A to B which do not include this malfunctioning valve/pipe. Typically, all routes throughout the factory are generated, or at least all routes from A to B, e.g., in offline, and then, responsive to a query, those routes from A to B which include this malfunctioning valve/pipe are filtered out and/or routes which include certain nodes which are already in use, are also filtered out. Then, a route selected from among those routes not filtered out, may be used at least until the faulty valve/pipe is restored to function, at which point the original route, which did include the now-functioning valve/pipe, may or may not be restored to use instead of the route selected from among routes not filtered out.

Certain embodiments of the present invention seek to provide circuitry typically comprising at least one processor in communication with at least one memory, with instructions stored in such memory executed by the processor to provide functionalities which are described herein in detail. Any functionality described herein may be firmware-implemented or processor-implemented, as appropriate.

It is appreciated that any reference herein to, or recitation of, an operation being performed is, e.g. if the operation is performed at least partly in software, intended to include both an embodiment where the operation is performed in its entirety by a server A, and also to include any type of “outsourcing” or “cloud” embodiments in which the operation, or portions thereof, is or are performed by a remote processor P (or several such), which may be deployed off-shore or “on a cloud”, and an output of the operation is then communicated to, e.g. over a suitable computer network, and used by, server A. Analogously, the remote processor P may not, itself, perform all of the operations, and, instead, the remote processor P itself may receive output/s of portion/s of the operation from yet another processor/s P′, may be deployed off-shore relative to P, or “on a cloud”, and so forth.

The present invention typically includes at least the following embodiments:

### Embodiment 1

A method for facilitating manufacturing in a factory, the method comprising: receiving a P&ID diagram of equipment elements and control modules in the factory; and/or using a hardware processor to identify, and/or to provide an output indication of, material flow routes that connect at least some of the equipment elements and/or control modules typically including, for each route, an ordered sequence of equipment elements and/or control modules from a starting point e.g. source to a destination and a direction.

A particular advantage of this embodiment is facilitation of process manufacturing automation.

### Embodiment 2

The method according to any of the preceding embodiments and wherein all routes from a given source to a given destination are identified.

### Embodiment 3

The method according to any of the preceding embodiments and wherein the method identifies only routes whose direction is valid, taking into account all directional control modules, such as motors, along the routes.

### Embodiment 4

The method according to any of the preceding embodiments and wherein, upon request, the method filters out a subset of routes from the given source to the given destination which do not comply with a user-provided route filtering criterion.

### Embodiment 5

The method according to any of the preceding embodiments and wherein the subset of routes comprises all routes which pass through a given factory equipment element and/or given control module, thereby to reduce down-time by facilitating re-routing each time a given factory equipment element, line, and/or given control module is malfunctioning.

### Embodiment 6

The method according to any of the preceding embodiments and also comprising identifying all control modules along a given route that need to be opened in order to ensure that material flows from said source element to said destination element via said given route.

### Embodiment 7

The method according to any of the preceding embodiments and and also comprising identifying all control modules that need to be closed in order to ensure that material does not flow via any route other than said route.

### Embodiment 8

The method according to any of the preceding embodiments and also comprising manufacturing goods in the factory typically using a formula or recipe, the manufacturing including combining materials wherein material flow routes to combine the materials are selected based on said output indication.

Materials may include manufactured supplies, raw materials or any other ingredients.

### Embodiment 9

The method according to any of the preceding embodiments and wherein the P&ID diagram is converted to vector format.

### Embodiment 10

The method according to any of the preceding embodiments wherein P&ID elements in the P&ID diagram are recognized.

### Embodiment 11

The method according to any of the preceding embodiments wherein pipes in the P&ID diagram are recognized as pipes and each pipe's flow direction is defined.

### Embodiment 12

The method according to any of the preceding embodiments wherein at least one symbol in the P&ID diagram is recognized and classified.

### Embodiment 13

The method according to any of the preceding embodiments wherein tanks pipes in the P&ID diagram are defined as tanks.

### Embodiment 14

The method according to any of the preceding embodiments wherein process unit components are defined.

### Embodiment 15

The method according to any of the preceding embodiments wherein the process unit components which are defined include at least one inner control module of at least one tank.

### Embodiment 16

The method according to any of the preceding embodiments wherein the process unit components which are defined include at least one connection port.

### Embodiment 17

The method according to any of the preceding embodiments wherein the process unit components which are defined include external inflows and outflows.

### Embodiment 18

The method according to any of the preceding embodiments wherein the process unit components which are defined include at least one process unit.

### Embodiment 19

The method according to any of the preceding embodiments wherein the process unit components which are defined include at least one area.

### Embodiment 20

The method according to any of the preceding embodiments wherein the process unit components which are defined include at least one flow route.

### Embodiment 21

The method according to any of the preceding embodiments which includes defining at least one control module as a common or shared control module.

### Embodiment 22

The method according to any of the preceding embodiments and also comprising storing editable phase templates and wherein phases are defined based on the editable phase templates.

### Embodiment 23

The method according to any of the preceding embodiments wherein said control modules include at least one sensor sensing a state of at least one of the equipment elements and/or control modules.

### Embodiment 24

The method according to any of the preceding embodiments wherein said control modules include at least one actuator such as a motor/engine or valve.

### Embodiment 25

The method according to any of the preceding embodiments wherein said control modules are controlled by respective PLC controllers.

### Embodiment 26

The method according to any of the preceding embodiments wherein said equipment elements include at least one tank.

### Embodiment 27

The method according to any of the preceding embodiments wherein control modules are attached to at least one unit e.g., to at least one of said equipment elements.

### Embodiment 28

A hardware processor configured to perform the method according to any of the preceding embodiments.

### Embodiment 29

A computer program product, comprising a non-transitory tangible computer readable medium having computer readable program code embodied therein, said computer readable program code adapted to be executed to implement a method for facilitating manufacturing in a factory, the method comprising: receiving a P&ID diagram of equipment elements and control modules in the factory; and/or using a hardware processor to identify, and/or to provide an output indication of, material flow routes that connect at least some of the equipment elements and/or control modules including, for each route, an ordered sequence of equipment elements and/or control modules from a source to a destination and a direction.

Also provided, excluding signals, is a computer program comprising computer program code means for performing any of the methods shown and described herein when said program is run on at least one computer; and a computer program product, comprising a typically non-transitory computer-usable or-readable medium e.g. non-transitory computer-usable or -readable storage medium, typically tangible, having a computer readable program code embodied therein, said computer readable program code adapted to be executed to implement any or all of the methods shown and described herein. The operations in accordance with the teachings herein may be performed by at least one computer specially constructed for the desired purposes, or a general purpose computer specially configured for the desired purpose by at least one computer program stored in a typically non-transitory computer readable storage medium. The term “non-transitory” is used herein to exclude transitory, propagating signals or waves, but to otherwise include any volatile or non-volatile computer memory technology suitable to the application.

Any suitable processor/s, display and input means may be used to process, display e.g. on a computer screen or other computer output device, store, and accept information such as information used by or generated by any of the methods and apparatus shown and described herein; the above processor/s, display and input means including computer programs, in accordance with all or any subset of the embodiments of the present invention. Any or all functionalities of the invention shown and described herein, such as but not limited to operations within flowcharts, may be performed by any one or more of at least one conventional personal computer processor, workstation, or other programmable device or computer or electronic computing device or processor, either general-purpose or specifically constructed, used for processing; a computer display screen and/or printer and/or speaker for displaying; machine-readable memory such as flash drives, optical disks, CDROMs, DVDs, BluRays, magnetic-optical discs or other discs; RAMs, ROMs, EPROMS, EEPROMs, magnetic or optical or other cards, for storing, and keyboard or mouse for accepting. Modules illustrated and described herein may include any one or combination or plurality of a server, a data processor, a memory/computer storage, a communication interface (wireless (e.g. BLE) or wired (e.g. USB)), a computer program stored in memory/computer storage.

The term “process” as used above is intended to include any type of computation or manipulation or transformation of data represented as physical, e.g., electronic, phenomena which may occur or reside e.g., within registers and/or memories of at least one computer or processor. Use of nouns in singular form is not intended to be limiting; thus, the term processor is intended to include a plurality of processing units which may be distributed or remote, the term server is intended to include plural typically interconnected modules running on plural respective servers, and so forth.

The above devices may communicate via any conventional wired or wireless digital communication means, e.g., via a wired or cellular telephone network or a computer network such as the Internet.

The apparatus of the present invention may include, according to certain embodiments of the invention, machine readable memory containing or otherwise storing a program of instructions which, when executed by the machine, implements all or any subset of the apparatus, methods, features, and functionalities of the invention shown and described herein. Alternatively, or in addition, the apparatus of the present invention may include, according to certain embodiments of the invention, a program as above which may be written in any conventional programming language, and optionally a machine for executing the program, such as but not limited to a general-purpose computer which may optionally be configured or activated in accordance with the teachings of the present invention. Any of the teachings incorporated herein may, wherever suitable, operate on signals representative of physical objects or substances.

The embodiments referred to above, and other embodiments, are described in detail in the next section.

Any trademark occurring in the text or drawings is the property of its owner and occurs herein merely to explain or illustrate one example of how an embodiment of the invention may be implemented.

Unless stated otherwise, terms such as, “processing”, “computing”, “estimating”, “selecting”, “ranking”, “grading”, “calculating”, “determining”, “generating”, “reassessing”, “classifying”, “generating”, “producing”, “stereo-matching”, “registering”, “detecting”, “associating”, “superimposing”, “obtaining”, “providing”, “accessing”, “setting” or the like, refer to the action and/or processes of at least one computer/s or computing system/s, or processor/s or similar electronic computing device/s or circuitry, that manipulate and/or transform data which may be represented as physical, such as electronic, quantities e.g. within the computing system's registers and/or memories, and/or may be provided on-the-fly, into other data which may be similarly represented as physical quantities within the computing system's memories, registers or other such information storage, transmission or display devices or may be provided to external factors e.g. via a suitable data network. The term “computer” should be broadly construed to cover any kind of electronic device with data processing capabilities, including, by way of non-limiting example, personal computers, servers, embedded cores, computing system, communication devices, processors (e.g., digital signal processor (DSP), microcontrollers, field programmable gate array (FPGA), application specific integrated circuit (ASIC), etc.), and other electronic computing devices. Any reference to a computer, controller, or processor is intended to include one or more hardware devices e.g., chips, which may be co-located or remote from one another. Any controller or processor may, for example, comprise at least one CPU, DSP, FPGA, or ASIC, suitably configured in accordance with the logic and functionalities described herein.

Any feature or logic or functionality described herein may be implemented by processor/s or controller/s configured as per the described feature or logic or functionality, even if the processor/s or controller/s are not specifically illustrated for simplicity. The controller or processor may be implemented in hardware, e.g., using one or more Application-Specific Integrated Circuits (ASICs) or Field-Programmable Gate Arrays (FPGAs), or may comprise a microprocessor that runs suitable software, or a combination of hardware and software elements.

The present invention may be described, merely for clarity, in terms of terminology specific to, or references to, particular programming languages, operating systems, browsers, system versions, individual products, protocols and the like. It will be appreciated that this terminology or such reference/s is intended to convey general principles of operation clearly and briefly, by way of example, and is not intended to limit the scope of the invention solely to a particular programming language, operating system, browser, system version, or individual product or protocol. Nonetheless, the disclosure of the standard or other professional literature defining the programming language, operating system, browser, system version, or individual product or protocol in question, is incorporated by reference herein in its entirety.

Elements separately listed herein need not be distinct components, and alternatively may be the same structure. A statement that an element or feature may exist is intended to include (a) embodiments in which the element or feature exists; (b) embodiments in which the element or feature does not exist; and (c) embodiments in which the element or feature exist selectably, e.g., a user may configure or select whether the element or feature does or does not exist.

Any suitable input device, such as but not limited to a sensor, may be used to generate or otherwise provide information received by the apparatus and methods shown and described herein. Any suitable output device or display may be used to display or output information generated by the apparatus and methods shown and described herein. Any suitable processor/s may be employed to compute or generate or route, or otherwise manipulate or process information as described herein, and/or to perform functionalities described herein and/or to implement any engine, interface, or other system illustrated or described herein. Any suitable computerized data storage e.g., computer memory, may be used to store information received by or generated by the systems shown and described herein. Functionalities shown and described herein may be divided between a server computer and a plurality of client computers. These or any other computerized components shown and described herein may communicate between themselves via a suitable computer network.

The system shown and described herein may include user interface/s e.g. as described herein, which may, for example, include all or any subset of an interactive voice response interface, automated response tool, speech-to-text transcription system, automated digital or electronic interface having interactive visual components, web portal, visual interface loaded as web page/s or screen/s from server/s via communication network/s to a web browser or other application downloaded onto a user's device, automated speech-to-text conversion tool, including a front-end interface portion thereof, and back-end logic interacting therewith. Thus, the term user interface or “UI” as used herein includes also the underlying logic which controls the data presented to the user e.g. by the system display and receives and processes and/or provides to other modules herein, data entered by a user e.g. using her or his workstation/device.

### BRIEF DESCRIPTION OF THE DRAWINGS

Example embodiments are illustrated in FIGS. 1-28 herein, and specifically:

FIGS. 1-2, 4-27 are simplified diagrams of example embodiments; and

FIGS. 3 and 28 are simplified flowchart illustrations of methods according to any embodiment shown and described herein which may be used in conjunction with any of the embodiments shown and described in FIGS. 1-2, 4-27. Also, any operation shown in FIG. 3 may be provided in conjunction with, or replaced by, any operation in FIG. 28, and vice versa. It is appreciated that in FIG. 3, the top and bottom blocks of each of the 3 columns illustrated, comprise inputs and outputs respectively of the operations in the relevant column.

In the block diagrams, arrows between modules may be implemented as APIs and any suitable technology may be used for interconnecting functional components or modules illustrated herein in a suitable sequence or order e.g. via a suitable API/Interface. For example, state of the art tools may be employed, such as but not limited to Apache Thrift and Avro which provide remote call support. Or, a standard communication protocol may be employed, such as but not limited to HTTP or MQTT, and may be combined with a standard data format, such as but not limited to JSON or XML. According to one embodiment, one of the modules may share a secure API with another. Communication between modules may comply with any customized protocol or customized query language, or may comply with any conventional query language or protocol.

Methods and systems included in the scope of the present invention may include any subset or all of the functional blocks shown in the specifically illustrated implementations by way of example, in any suitable order e.g. as shown. Flows may include all or any subset of the illustrated operations, suitably ordered e.g., as shown. Tables herein may include all or any subset of the fields and/or records and/or cells and/or rows and/or columns described.

Computational, functional, or logical components described and illustrated herein can be implemented in various forms, for example, as hardware circuits such as but not limited to custom VLSI circuits or gate arrays or programmable hardware devices such as but not limited to FPGAs, or as software program code stored on at least one tangible or intangible computer readable medium and executable by at least one processor, or any suitable combination thereof. A specific functional component may be formed by one particular sequence of software code, or by a plurality of such, which collectively act or behave or act as described herein with reference to the functional component in question. For example, the component may be distributed over several code sequences, such as but not limited to objects, procedures, functions, routines, and programs, and may originate from several computer files which typically operate synergistically.

Each functionality or method herein may be implemented in software (e.g. for execution on suitable processing hardware such as a microprocessor or digital signal processor), firmware, hardware (using any conventional hardware technology such as Integrated Circuit technology) or any combination thereof.

Functionality or operations stipulated as being software-implemented may alternatively be wholly or fully implemented by an equivalent hardware or firmware module, and vice-versa. Firmware implementing functionality described herein, if provided, may be held in any suitable memory device, and a suitable processing unit (aka processor) may be configured for executing firmware code. Alternatively, certain embodiments described herein may be implemented partly or exclusively in hardware, in which case all or any subset of the variables, parameters, and computations described herein may be in hardware.

Any module or functionality described herein may comprise a suitably configured hardware component or circuitry. Alternatively or in addition, modules or functionality described herein may be performed by a general purpose computer, or, more generally, by a suitable microprocessor, configured in accordance with methods shown and described herein, or any suitable subset, in any suitable order, of the operations included in such methods, or in accordance with methods known in the art.

Any logical functionality described herein may be implemented as a real time application, if and as appropriate, and which may employ any suitable architectural option, such as but not limited to FPGA, ASIC, or DSP or any suitable combination thereof.

Any hardware component mentioned herein may in fact include either one or more hardware devices e.g., chips, which may be co-located or remote from one another.

Any method described herein is intended to include within the scope of the embodiments of the present invention also any software or computer program performing all or any subset of the method's operations, including a mobile application, platform, or operating system e.g., as stored in a medium, as well as combining the computer program with a hardware device to perform all or any subset of the operations of the method.

Data can be stored on one or more tangible or intangible computer readable media stored at one or more different locations, different network nodes, or different storage devices at a single node or location.

It is appreciated that any computer data storage technology, including any type of storage or memory and any type of computer components and recording media that retain digital data used for computing for an interval of time, and any type of information retention technology, may be used to store the various data provided and employed herein. Suitable computer data storage or information retention apparatus may include apparatus which is primary, secondary, tertiary, or off-line; which is of any type or level or amount or category of volatility, differentiation, mutability, accessibility, addressability, capacity, performance and energy use; and which is based on any suitable technologies such as semiconductor, magnetic, optical, paper, and others.

### DETAILED DESCRIPTION OF CERTAIN EMBODIMENTS

A particular advantage of embodiments herein is that in modern factories, a single manufacturing process may use multiple routes when creating even a single product, and there are in addition cleaning routes and HAZOP routes; thus the automation herein greatly facilitates the manufacturing process by saving large amounts of time and error involved in defining all required routes (and flows) manually as occurs in many factories in practice, at this time. Inter alia, automated discovery of (all) routes e.g. auto route discovery, aka auto discovery according to any method herein, may generate outputs which identify alternative routes achieving similar or identical material flow. This is useful in case of an equipment breakdown (e.g., faulty valve, pump or pipe leakage) or for CIP (cleaning in place) where typically, factory personnel may want to have visibility to the various cleaning routes traversing through a segment that needs particular cleaning. Typically, autodiscovery allows the designer to see what line segments will be filled with material (potentially contaminated) beyond the main flow between source and target (aka destination) of the route as material travels through any line/pipe unless and until the material encounters a closed valve.

Certain embodiments include a method for facilitating production of goods in a factory, the method comprising receiving a P&ID diagram of equipment elements and/or control modules in the factory; and/or identifying routes that connect at least some of the equipment elements and/or control modules including, for each route, an ordered sequence of equipment elements and/or control modules from a source to a destination, thereby to define a direction for each route.

Optionally, the method may also comprise finding a shortest route extending from a given source element to a given destination element. Given a factory which provides material flow via, say, pipes running from one container to another, the system typically stores a graph (e.g. as described herein:
https://en.wikipedia.org/wiki/Graph theory #:\tilde{ }:text=In % 20mathematics %2C % 20gra ph % 20theory % 20is,also % 20called%20links % 20or % 20lines) which represents all pipes in the factory.

The system typically builds a graph of connected elements which connects control equipment and tanks/containers, via lines or pipes, where each pipe between two connected elements may be defined as an edge in the graph and each connected element may be defined as a node or vertex in the graph. Then, a suitable search e.g. breadth first search aka BFS is used to traverse and scan the graph model, as a base. the graph may be searched (e.g., using BFS) to find routes or paths from one equipment or node to another.

Using this graph, the system may (e.g. by using a BFS algorithm to search the graph data structure) determine all possible paths between a given pair of containers e.g. a pair defined by a human user and/or may determine, for a given pair of paths, which path portions (edges and/or nodes), if any, overlap and/or may prevent plural overlapping routes from not operating at the same time responsive to an operator having commanded the plural routes, via HMI, to operate simultaneously. The system may do this e.g., by closing off material flow to one or both such routes and/or providing an alert indication that a command has been given, e.g., via the HMI, to operate plural overlapping routes simultaneously.

Knowing all possible paths enable the system to build all operating sequences logic for all possible routes in the PLC, typically offline. Subsequently, any one of these operating sequences may be selected by a user, dynamically. Alternatively, or in addition, the connection between the manufacturing process and the physical components is better understood and may be presented visually, to allow better troubleshooting and/or optimization of the manufacturing process.

It is appreciated that it may be desired to identify overlap between paths; system rules may define some types of overlap as good or acceptable, and others as bad or unacceptable, to be flagged e.g., by providing an alert to a user. For example, in a mixer, overlap may be acceptable.

Overlapping may be handled or identified by stopping recursive computation (e.g., defining a stopping criterion for the recursion) when an edge or node is approached, when this has already been approached in the past. Thus, typically, the system may mark edges/nodes as visited, so the system can stop iterations if a “visited” edge/node is encountered.

It is appreciated that paths which do not overlap may be vertex-independent (alternatively, internally vertex-disjoint), or may be edge-independent (or edge-disjoint) having no internal edge in common. Internally vertex-disjoint paths are edge-disjoint, but not necessarily vice versa.

Optionally, the method for facilitating production of goods may also comprise identifying route/s extending from a given source element to a given destination element which do not include a given intermediate element, to reduce or eliminate production down-time when elements in the factory malfunction, by enabling a command to be given, regarding a process such as a material transfer process which normally utilizes a first route extending from the given source element to the given destination element via certain elements, to temporarily use an alternative route, other than the first route, which bypasses any element from among said certain elements, which is malfunctioning.

Optionally, a first command is given, at least once, regarding a process such as a material transfer process, which normally utilizes a first route extending from the given source element to the given destination element via certain elements, to temporarily use an alternative route, other than the first route, which bypasses any element E from among said certain elements, which is malfunctioning; and, when element E is restored to function, a second command is given to terminate use of the alternative route, and to utilize instead the first route.

Optionally, notification is provided, for each route for which material flows out of the route due to open valves, which, once closed, would block the material from flowing out of the route.

Optionally, a set of routes is identified including plural routes from a given source element to a given destination element, and wherein a subset of the plural routes which conforms to a user-defined route-filtering criterion, is identified, thereby to facilitate material flow from the given source element to the given destination element, by generating at least one automatically generated PLC command which selects a best route from the given source element to the given destination element where bestness is defined according to the user-defined route-filtering criterion.

A method for operating a factory according to certain embodiments is now described. All or any subset of the following operations may be provided, in any suitable order e.g., as follows:
a. Offline, generating a “recognized modules” library or DB storing plural recognized modules which includes attributes for each module, (such as all or any subset of these attributes: list of module's ports, module's connection points, locations of ports, flow direction (in/out), how to activate/deactivate module, off mode flows, on mode flows)
b. For each of plural factories which use the system presented, perform all or any subset of operations b1-b7, in any suitable order e.g., as follows.
Operation b1. Receiving a diagram in PNID aka P&ID e.g., in pdf or Dwg, or any other suitable format of PNID) of the factory, including symbols and all connections between ports defined for all modules respectively represented by the symbols. For example, a client may draw factory P&ID/s inside the system of the invention, existing P&ID drawing/s may be imported/uploaded, and for a combination, both upload and draw inside the system of the invention.
Operation b2. identifying module symbols, and connections between the symbols for the modules, in the diagram. Typically, once the symbols have been identified, all other indicia are examined to determine which indicia are indicative of connections between the symbols. For example, given a symbol which has a certain perimeter, the system may travel along the perimeter to identify lines or other elongate elements extending outward from the perimeter, and determine whether these lines, when followed, eventually terminate at a perimeter of some other symbol. If so, system heuristics or rules may determine that this line is necessarily a connection e.g., pipe, conveyor, or free-fall. An example of an elongate element other than a line is any conventional symbol in the industry indicating a conveyor.

Typically, pipes are identified as being valid conduits for specific types of material such as cleaning fluids, acids, fuels, steam, or water. Typically, containers are labelled to indicate the material it is intended to contain e.g., steam, water, etc., and the system then assumes that pipes extending from these containers are suitable for conveying these materials.
Operation b3. recognizing each module symbol by either classifying each module symbol automatically as one of the plural recognized modules, or presenting each module symbol to the end-user for manual classification as one of the plural recognized modules.

Typically, in addition to recognition of module symbols, the system also identifies properties of equipment such as directionality e.g., by reference to an internal database which distinguishes a pump (e.g.) which is unidirectional in a first direction from the same pump which is unidirectional in the opposite direction. For example, the pump unidirectional in the first and opposite directions may be mirror images of one another. Another example of a unidirectional element is a non-return valve which enables flow in a first direction and prevents flow in the opposite direction. A user can classify unrecognized symbols and/or may manually select one of the modules in the “recognized modules” library, for each unrecognized symbol; the system may then store the unrecognized symbol as an alternative symbol for the user-selected module in the library.

Typically, the system is configured to read input from the DWG (say) file, then classify that content e.g., as described herein. For example, content such as lines, texts, or blocks (where each block typically comprises a set e.g. grouped list of related lines and shapes) is classified, where lines may be classified into pipes, and shapes and/or blocks may be classified into control and equipment modules. A suitable classifier may be trained using manual user input, or classification may be performed by a human user; the system may show the user various blocks and s/he defines their classification, typically by selecting from a predefined system library storing predefined equipment and control modules.

Typically, once a symbol is classified, all instances of that symbol in the diagram are automatically so classified.

To facilitate relating of texts to symbols, texts in the diagram may be parsed using predefined logic.
Operation b4. for all (or at least some) pairs of modules a, b in the factory (e.g. all possible pairs of ports in modules a, b respectively) computing (e.g. offline), routes (e.g. all possible routes—hundreds of such routes may exist) from (a given “source” port of) source module a to (a given “target” or “destination” port of) target module b, by stringing together connections between module ports as identified e.g. as described above, thereby to define route segments which, together, form routes. Computation may be based on BFS, and may be recursive. It is appreciated that routes are typically directional, extending from a source to a destination. Typically, a path which extends from a source to a destination, notwithstanding which equipment lies along the path, e.g., a pump or non-return valve, is unidirectional in the wrong direction, is considered invalid, and is not identified as a route from that source to that destination.

Typically, certain symbols are identified as constituting only a starting point or source of a route, and cannot be a destination e.g., a connection to the water mains. Other symbols may be defined as constituting only an endpoint or destination of a route, and cannot be a route, e.g., a drain to a sewage outlet/pipe.

When generating routes, unrecognized symbols may be treated like a picture, however, typically, the system takes into account those elements (even if unrecognized) through which material can flow.

Typically, each time a route is identified which extends between a starting point A and an endpoint B, the system travels along the route to identify junctions falling along the route which potentially cause material flow other than along the route itself, unless connections extending outward from the junction, which are not part of the route, are sealed off e.g., by valves. This is advantageous in order to minimize loss of material through this spillage and/or in order to minimize cleaning thereafter, and/or in order to eliminate contamination between adjacent simultaneously operating routes, and to maximize utility of the factory by enabling a maximum number of routes to function simultaneously without mutual contamination.

Typically, routes which include repeated segments are not included in the system's stored routes e.g., a route from A to B to C to D is included, however a route from A to B to C to B to C to B to C to D, is not included.

Typically, for each pair of routes identified, the system determines whether there is or is not any overlap between the two routes in order to differentiate between pairs of routes which are possibly incapable of operating simultaneously, due to (unacceptable) overlap therebetween, one the one hand, and pairs of routes which are capable of operating simultaneously, due to lack of overlap therebetween, on the other hand.
Operation b5. For each route segment between modules m1 and m2 (or “elements”—routes are typically computed from port to port of remote elements) that are adjacent along the route, and/or for each module and/or for each (input port, output port) pair, storing an implementation protocol determining which valves along the route segment should be opened, and which should be closed, which pumps along the route segment should be activated and which de-activated, for how long [e.g. what delay to allow before progressing in the sequence], and in which order to implement that route segment or in order to traverse that module.
Operation b6. At least once, receiving an instruction flow (e.g., for a new product to be made in the factory, or a change in the recipe of an existing product), each instruction commanding to move material from a first module in the factory to a second module, and determining a selected route, selected from among the possible routes (which may be pre-computed offline) between the first and second modules (e.g., by filtering out certain possible routes e.g., routes which traverse an out-of-order module or an out-of-order connection);
Operation b7. Generating PLC code which performs the implementation protocols for all route segments along the selected route, thereby to provide PLC code which moves the material from the first module to the second module; and when generating PLC codes, unrecognized symbols may be ignored, e.g., may be treated like a picture.

Optionally, PLC code for activation or deactivation of a route with plural segments may be generated by linking or concatenating implementational protocols of each segment along the route, in order. Typically, as explained herein, the order in which these protocols are linked for activation, is opposed to the order in which these protocols are linked for de-activation.
b8. Generating display files for display on control screens in the factory.

It is appreciated that any method herein may be employed to generate a list of control modules, e.g., from a PNID module, or such a list may be generated by hand.

A method for transformation of P&ID drawings into information data model (e.g., as described herein) of interconnected equipment and control modules, with functional relationships is now described in detail.

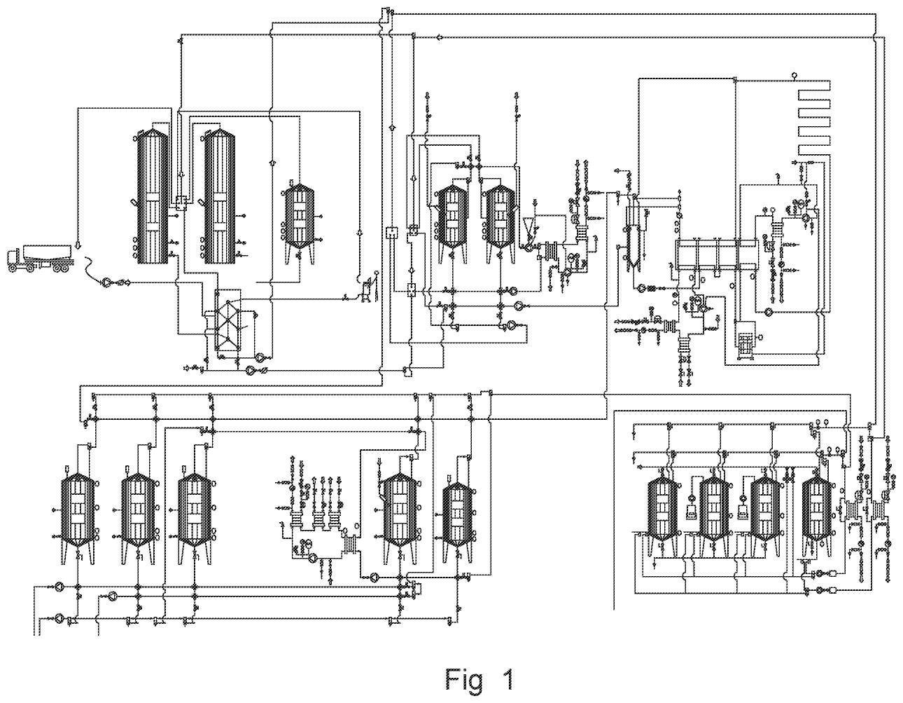

An example of a P&ID diagram is shown in FIG. 1.

Terms herein e.g., below, may be construed either in accordance with any definition thereof appearing in the prior art literature, or in accordance with the specification, or to include in their respective scopes, the following:

P&ID: A piping and instrumentation diagram is a detailed diagram in the process industry which shows piping and process equipment together with the instrumentation and control devices.

Equipment Modules: An equipment module may include an apparatus for transforming or holding goods for performing the different elements of procedural logic required to achieve the process task. Equipment modules may be contained within units, or may be shared between units in a process cell.

Control Modules: These may include sensors and/or actuators, and/or basic control logic that may act as either a regulating device, a state-oriented device, or a combination that is operated as a single device.

Non-Controllable modules and equipment: Manual controls and equipment which do not have electrical controls.

Ports: A connection point for an inflow or outflow for the Equipment or Control module.

Pipelines and flowlines: A connection between two ports. May connect ports from and to equipment or control modules.

Process Unit: e.g., based on the ISA-88 standard. A combination of equipment and control modules operating together, to execute a (typically major) processing activity.

Tank: A container that operates to hold materials, or execute a reaction. “Tank” may refer to any type of containers, reactors, and other content holding vessels.

Tank Inner Control Module: Any control equipment that is connected physically to the Tank and is a part of Tank's core functionality.

Main Tank: Any module which carries out the primary activity in the process unit's operations. This may be a mixer, reactor, or storage container.

Area level: Based on the ISA-88 standard. A logical, physical, or geographical group is determined by the site. The boundaries of the area level are decided by organizational or business criteria.

Vector model: Representation of the graphical data using geometric shapes such as points, lines, curves, and polygons.

Pipe: A connection from one P&ID element to another which provides a flow of material, water, or air. The pipe may have multiple connections to a few P&ID elements. it also may have open, non-connected ends which indicate external inflow or outflow.

Pipe Joint: A pipe may comprise plural interconnected legs, each leg connection representing a joint.

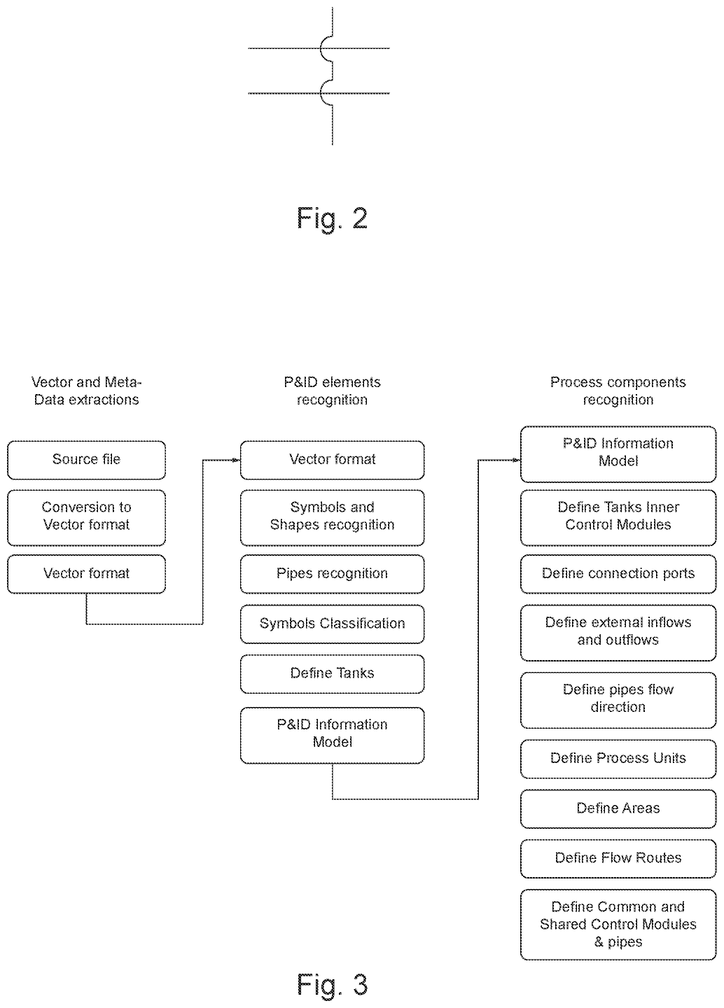

Pipe bridge: In some P&ID drawings, pipes intersections designed or displayed with a bridge or gap element e.g., as shown in FIG. 2.

Flow Route: A group of connected equipment, control modules, and pipes, which are used to transfer materials from one equipment to another.

Transformation process of P&ID drawings into DB of interconnected equipment and control modules, with functional relationships-an example is shown in FIG. 3.

The process typically includes all or any subset of the following, suitably ordered e.g., as follows:
a. vector and meta-data extraction
b. P&ID element recognition
c. process component recognition

Vector and Meta-Data extractions may include all or any subset of the following three embodiments:

Conversion to vector representation: Various file inputs formats might represent the P&ID drawing as vector and rasterized information. This conversion process is configured to read and understand the file input and transform it to structural P&ID information.

Process input: Various files formats with P&ID drawings.

Output: Vector model representing the shapes in the P&ID drawing.

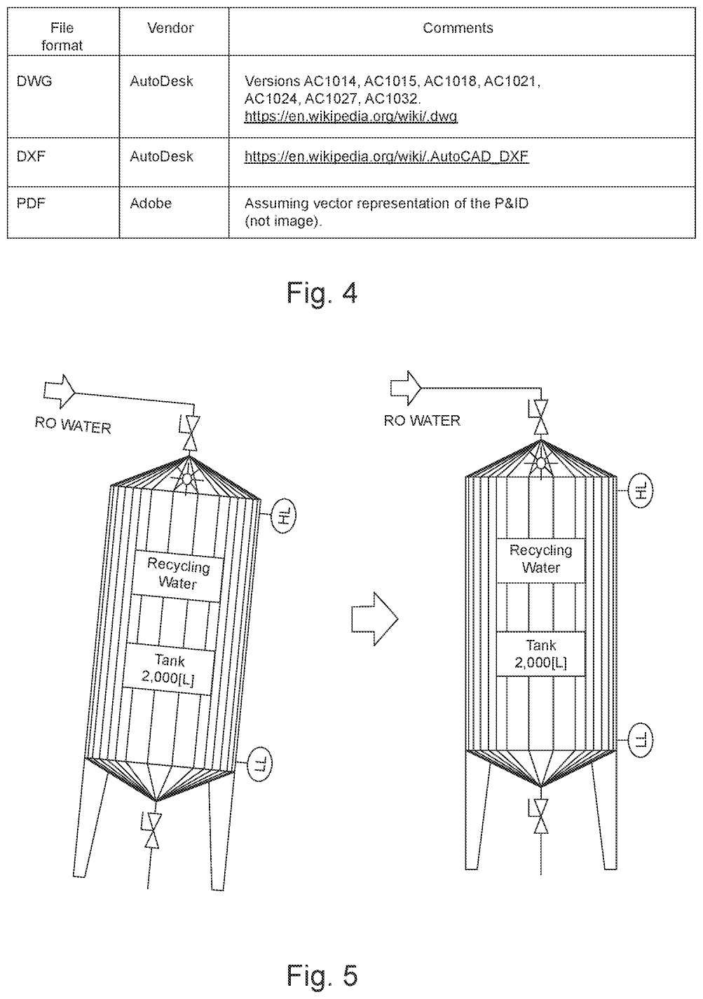

Vector formats: Various vector file formats such us DWG, DXF, SVG, and others, are used in the market by graphical software. The formats underlining model represents a vector-based model, including: dots, lines, various geometrical shapes, texts, textures.
Some of the vector formats such as DWG or DXF support grouping of elements into single groups and blocks, and support prototyping, providing reuse of such blocks over the diagram (for example reuse of the valve shapes).
Some of the vector formats such as DWG or DXF support attributes and annotations on the shapes, groups, and blocks models.
The system may extract from the vector format files the vector information and all the provided meta-data such as vectors types, vector name, vector group, and other attributes to support subsequent classification of elements such as “Pipe”, “Tank”, “valve”, etc., and functionality of the P&ID, for example “Valve On/Off”, “Valve PID”, etc. This may be done by the vector and vector group shapes and the textual descriptive information inside the vector attributes, and the vector surrounding texts.
Examples of file formats that may be supported by the system are shown in FIG. 4.

### Image Formats

The system may use the industry's 3^{rd} party tools, such OpenCV library for image recognition technology to convert rasterized images into vector model representation (image tracing).

The system may use the industry's 3^{rd} party tools, such as OpenCV, to discover lines and connections between various shapes.

### User Assisted Supplementation

For unidentified shapes and images on the drawing, the system may show these images and shape areas to a user and may ask the user to identify the respective shapes and symbols, including grouping related vectors into a single shape.

### Vector Alignment and Stabilization

The system may use 3^{rd} party solutions, such as OpenCV to align the resulting vector model to horizontal and vertical alignment. This tool may be used to identify horizontal and vertical lines, and align them with all the connected shapes and vectors, e.g. as shown in FIG. 5.

P&ID elements recognition may include all or any subset of the operations shown in FIG. 3.

### Symbols and Shapes Recognition

Based on the vector model, recognize and define symbols, by separating symbols and complex shapes from lines (piping) connections.

Input: Vector model of P&ID drawing, with or without meta-data, and with or without shape groups.

Output: P&ID information model, with identified P&ID symbols and their classifications, and the functional connection between them.

This recognition may be based on meta-data and/or on proximity and/or continuity and/or on vector comparison to an existing database of shapes.

### Based on Meta-Data

P&ID symbols may be identified based on the groups (blocks) of shapes, and their provided meta-data information such as group name, and any other custom texts added to the vector model. Each group of shapes may be defined as a P&ID symbol, for example a pair of two triangles with a common vertex may be classified, say, as a gate, or valve.

Re the embodiment based on proximity and continuity, any suitable technology known in the industry may be used to recognize groups of related shapes based on the proximity of their vector components.

A set of lines and shapes that has connection and intersection between them, may be considered as a group.

The group boundaries may be computed to distinguish from the grouped elements and the incoming or outgoing connection lines.

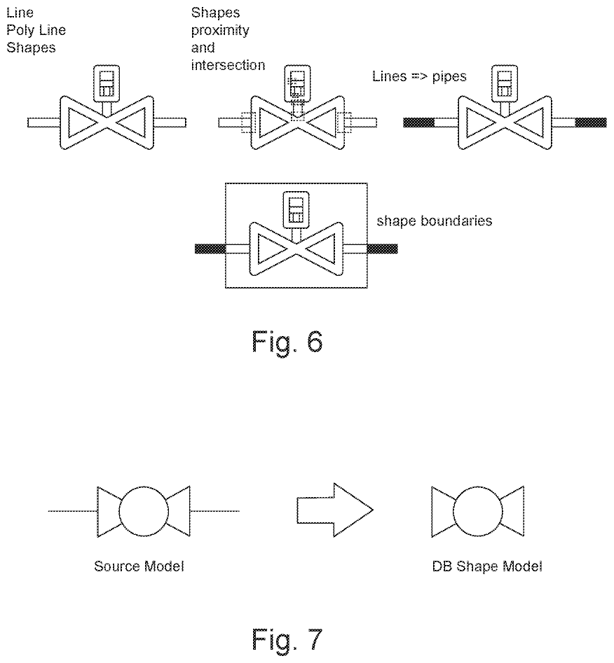

Connected lines (pipes): Boundaries may be adjusted until the last line element enters the boundary; e.g. as shown in FIG. 6.

Re the embodiment based on vector comparison to existing shapes DB, the system may define and manage a DB of a predefined groups of shapes. This DB may be used to compare and recognize similar shape groups within the P&ID drawing. The system may develop or utilize an industry 3^{rd} party solution such as OpenCV for vector shapes groups' comparison and similarity computations; e.g. as shown in FIG. 7.

### Texts Association

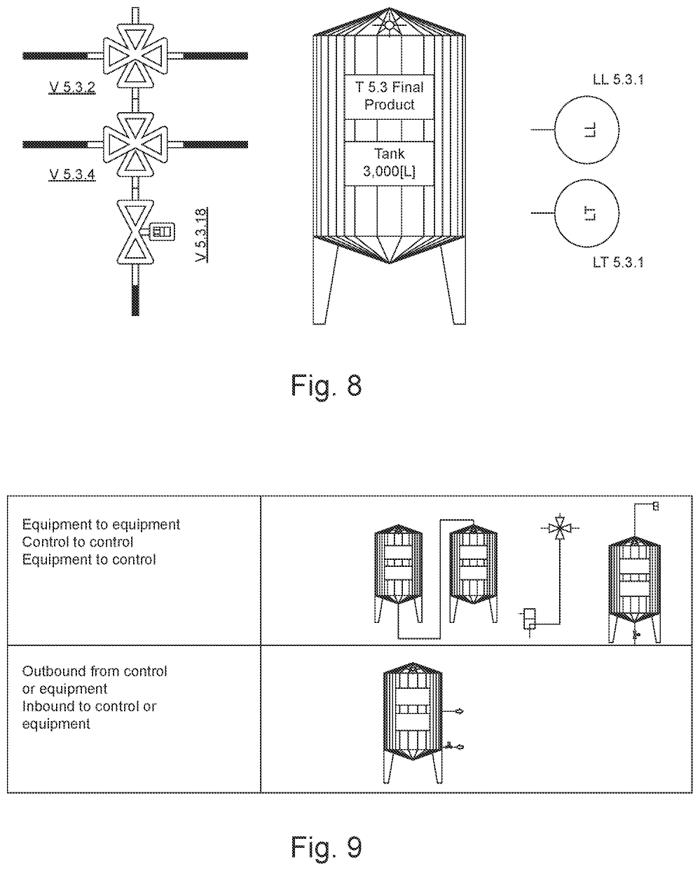

Text elements may be associated to the nearest group, or to the group that is inside its boundaries, based on proximity computation; e.g., as shown in FIG. 8.

### Pipe Recognition

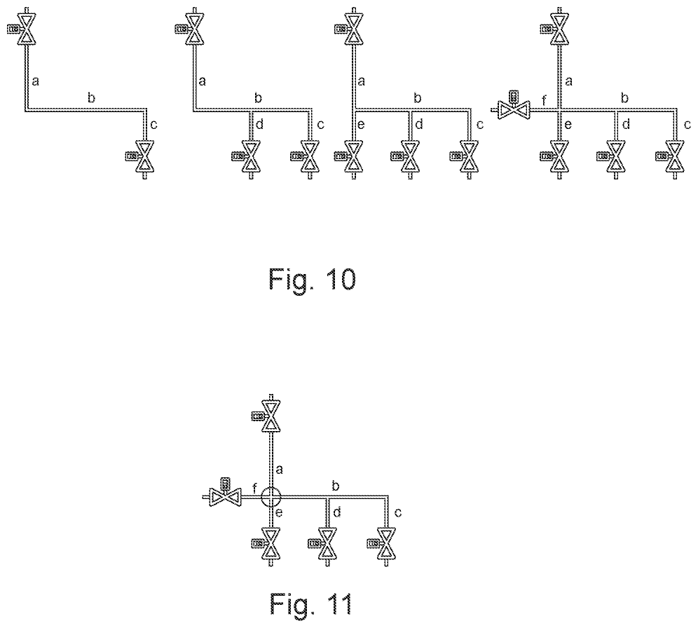

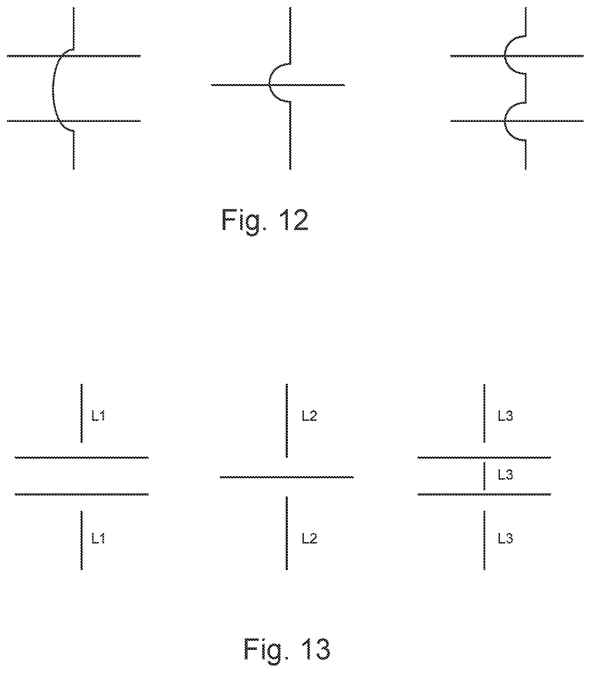

Graphical lines, dots, arcs, and other linear shapes, which are used to connect one symbol to another, may be classified as pipes e.g., as shown in the table of FIG. 9.
Line sets: A set of pipelines which leads from on symbol to another, may be grouped together as a single pipe with multiple connection ports e.g., as shown in FIG. 10.
Intersection bridges: The following bridges of lines intersections may be supported.
Cross lines: these may require a guided resolution from a user, to be defined as a joint or intersection bridge e.g., as shown in FIG. 11.
Arc bridge: May be referenced in the model as a bridge, based on its two-end connection to a pipes e.g., as shown in FIG. 12.
Gap bridge: May be computed as a bridge e.g., as shown in FIG. 13.

### Symbols Classification

Recognize repeatable symbols, and classify based on pre-existing DB of P&ID symbols as described above, based on ISO-14617 standard.
The system may define and manage or maintain a DB of P&ID symbols and their variations in the industry, as described above. Image recognition and vector model similarity algorithms may be used to identify similar symbols. The system may utilize industry 3^{rd} party solutions such as OpenCV for similarity computations.
Based on the DB of P&ID symbols and their variations in the industry, the identified symbols may be classified as controllable or non-controllable modules, connection ports may be defined, and port's flow direction may be configured.

### Define Tanks

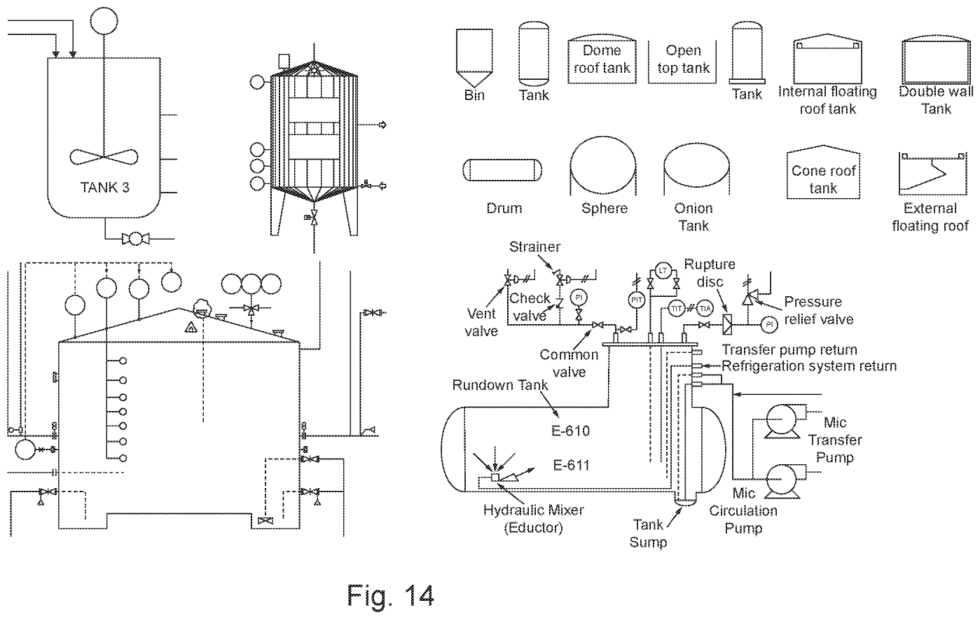

Recognition of Tanks, Reactors, and Containers shapes.
After recognition of the P&ID symbols and their connection pipes, the system may display to the user the various non-P&ID symbols shapes, and the user may be prompted to classify the relevant shapes as tanks, reactors, or containers e.g., as shown in FIG. 14.

### Non-Identified Shapes

Any non-identified or non-classified shapes may be stored in the information model as graphical annotation, without functional classification.
Process components recognition may include all or any subset of the operations shown in FIG. 3. Specifically:
The following process may define the functional classification of the P&ID diagram symbols and connections.
Input, e.g., as shown in FIG. 3, may comprise a P&ID information model, including symbols and their connections through pipes, which start from one symbol and ends at the other symbol. The P&ID process information model may stipulate functional role of symbols, and/or connections, and/or their combined utilization for the production process.

### Define Inner Tank Control Modules

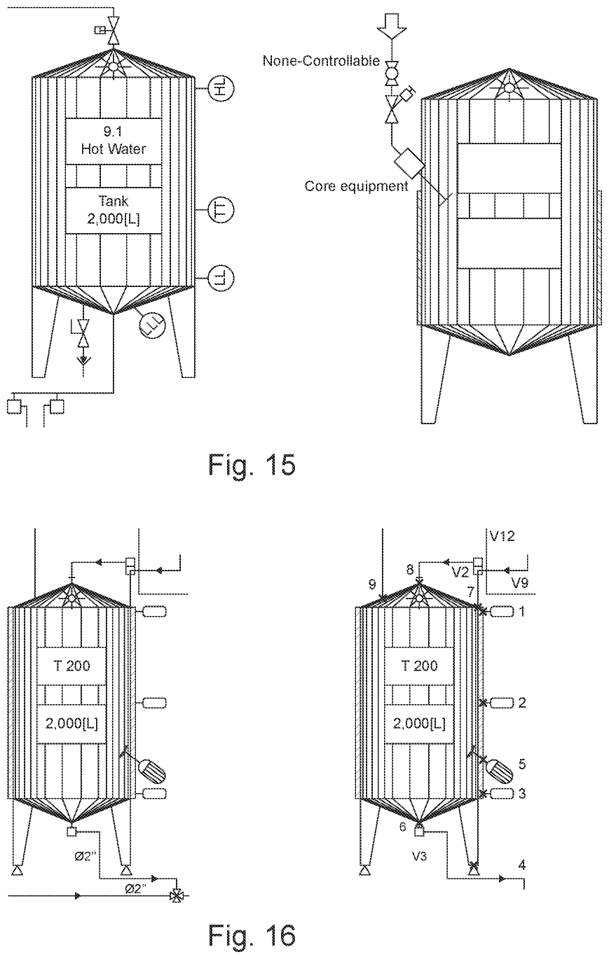

Identify the control modules which are attached and are a part of the tank, reactor, or container core equipment.
Use control equipment proximity on P&ID which does not have a connection pipe.
The P&ID of FIG. 15 represents a main container with a connected equipment and control modules:
As shown by x's in the tank represented on the right of FIG. 16, certain P&ID elements may be identified as the tank's inner elements.
1: Connection to Digital High-Level Sensor.
2: Connection to Analog Input Temperature.
3: Connection to Digital Low-Level Sensor.
4: Connection to Analog loadcell weight Sensor.
5: Connection to agitator motor.
6: Connection to pipe to discharge valve.
7: Connection to pipe to material circulation.
8: Connection to tank CIP (cleaning in place).
9: Connection to Tank water filling.
   For unrecognized P&ID shapes, which are adjusted to the tank, a user may be presented with a screen to define and classify their function.

### User-Assisted Identification

For the unidentified shapes and symbols, provide a user guided wizard to define the correct shape. The wizard may present the unrecognized vector elements to the user, and may allow the user to define classification for each vector element or group, based on the symbols in the P&ID DB or in the system's DB of P&ID symbols and their variations in the industry.

### Define Connection Ports

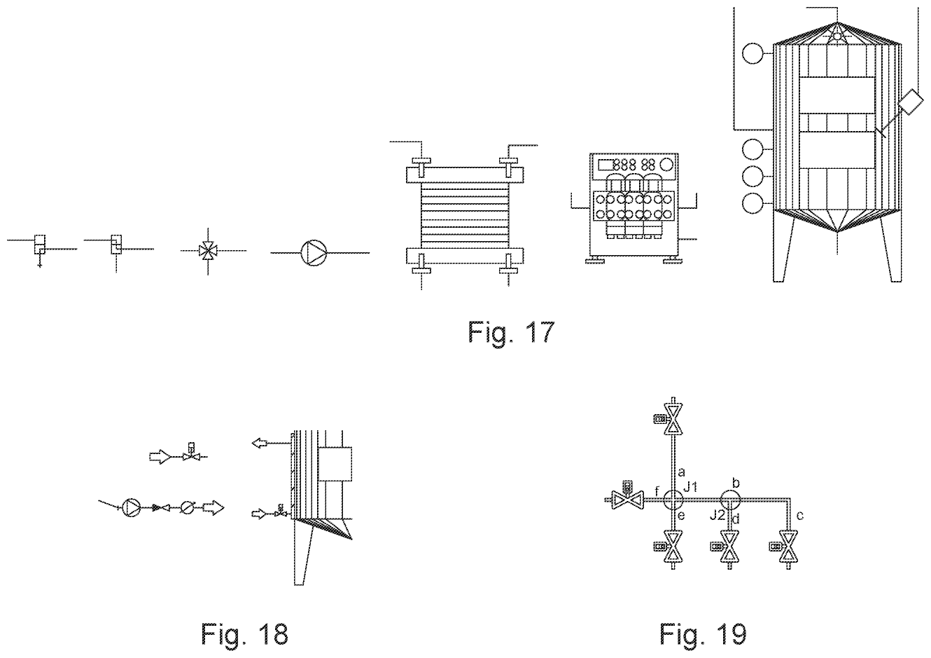

For the identified symbols, extract the definitions of required ports. Actual connected ports are computed from the P&ID model, based on the incoming and outgoing pipes to the symbol. For identified P&ID elements, the system may define the port flow direction, inflow, outflow, or both.
For unidentified elements or tanks, the user may configure the ports and their role e.g., as shown in FIG. 17.

### Define External Inflows and Outflows

Inflow and outflow ports are identified by pipes without input or output tanks or control module, and with an open-end connection into annotation graphics or non-controllable modules e.g., as shown in FIG. 18. To define pipe joints, intersection points of lines may be defined as joints, and may be referenced as a separate set of connection ports to the pipe, e.g., as shown in FIG. 19.

### Define Pipe Flow Directions

Pipes represented in a P&ID might have single or bi-directional flows.
Determination of the flow direction in the pipe may be computed based on the ports and their connected equipment or control module. Computation of specific pipe flow direction might be derived from the presiding and succeeding pipes.
The system may evaluate each pipeline. If a pipeline has at least one port with a direction, the flow direction of the pipe may be according to the port. If a pipeline has all connection ports as bi-directional, the pipe may be defined as bi-directional.
Each pipe joint may be computed for its own flow direction to its end point.

Define Processing Units

A processing unit may be defined based on the main equipment module of type tank, its inner controls, and its connected control modules.
The control module is defined as part of the processing unit when it has a direct connection to the unit through a pipe, and does not divide the flow into multiple directions. In cases when the diversion of the flow is to the same unit, it is defined as non-divide, and it is considered to be a part of the unit.
Units with inflow from external sources may be classified as a Raw Material Unit.

### Classifying a Unit as CIP

Units with outflow and inflow into the same Unit (A goes to B, B returns to A).
At least one of the equipment modules in the unit is connected to a chemical dosing system.
At least one of the equipment modules is connected to a heater system.
At least one inflow or outflow line may be heated.
There is flow control in the outflow line.
There is conductivity control in the inflow line.
   First, the system may recognize tank-based units, followed by a no-tank-based units.
   After identifying the units and their automatic classification, a user may review and confirm or adjust, as required.

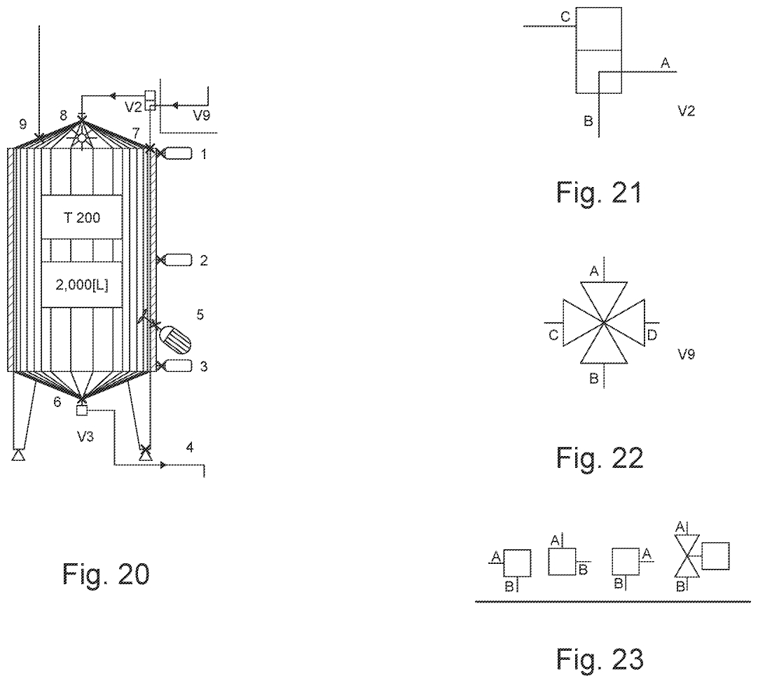

### Identification for Tank Based Unit, e.g., as Shown in FIG. 20

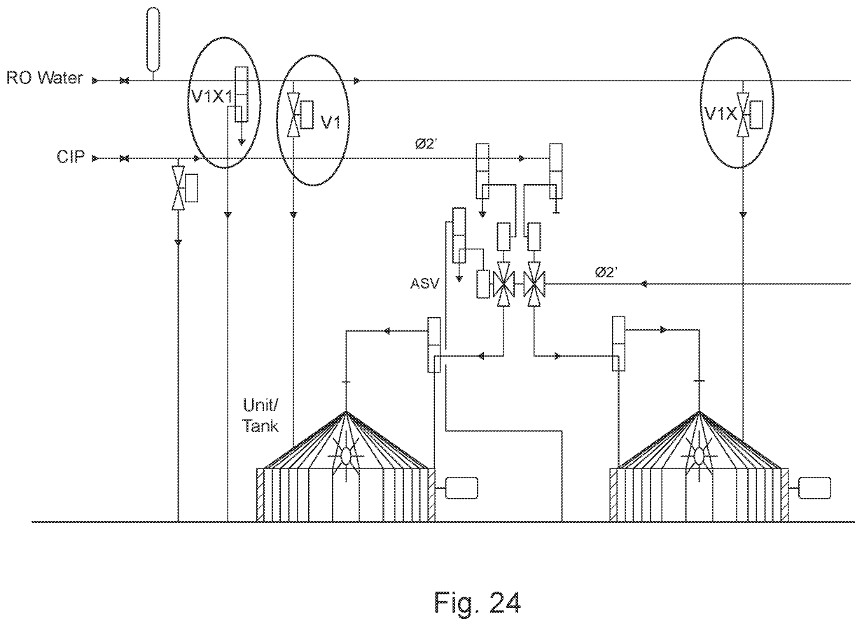

Element V2 is a valve on/off 3 ways with three connectors A, B, C. A is a connector indicated as an input, and B and C are output connectors. In the example, B and C are connected to the tank and considered a part of the unit. This layout is not a diversion; valve V2 is attached to the unit e.g., as shown in FIG. 21.
V9 is a Mix Proof valve. This type of valve has four connectors, A, B, C, and D. From A to B and from C to D there is always flow. If the valve is activated, the flow may be to all connectors. This valve is used to permit to divert the flow to all directions by activating the valve and to allow the flow between the fix points, without any danger of mixing between the flows. The valve is attached to the unit that may receive to/send from the unit. Hence, valve V9 is attached to the unit e.g., as shown in FIG. 22.
Stop valves are valves with two connection points, A and B. The flow is always between both connections, and may be with flow with activation of the valve (N.C. Normally Closed) or flow when the valve is not activated (N.O. Normally Open) e.g., as shown in FIG. 23.
Referring also to FIG. 24, Valve V1 is a stop valve butterfly type. Like other stop valves, it has two connections. One is connected to the unit, and the second to a line that supplies RO water to several tanks or units. Because one connection is directly connected to the tank in the unit, and the second connector is to a common line (as valve V1X and V1X1), valve V1 is considered as a part of the unit.

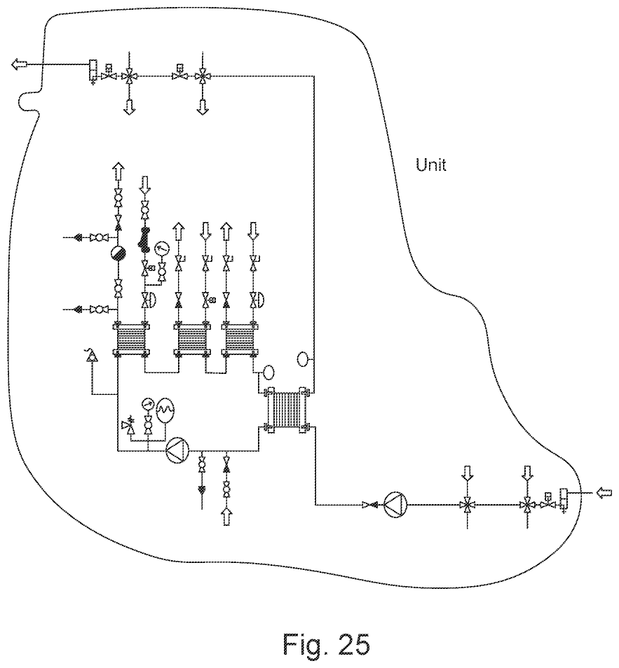

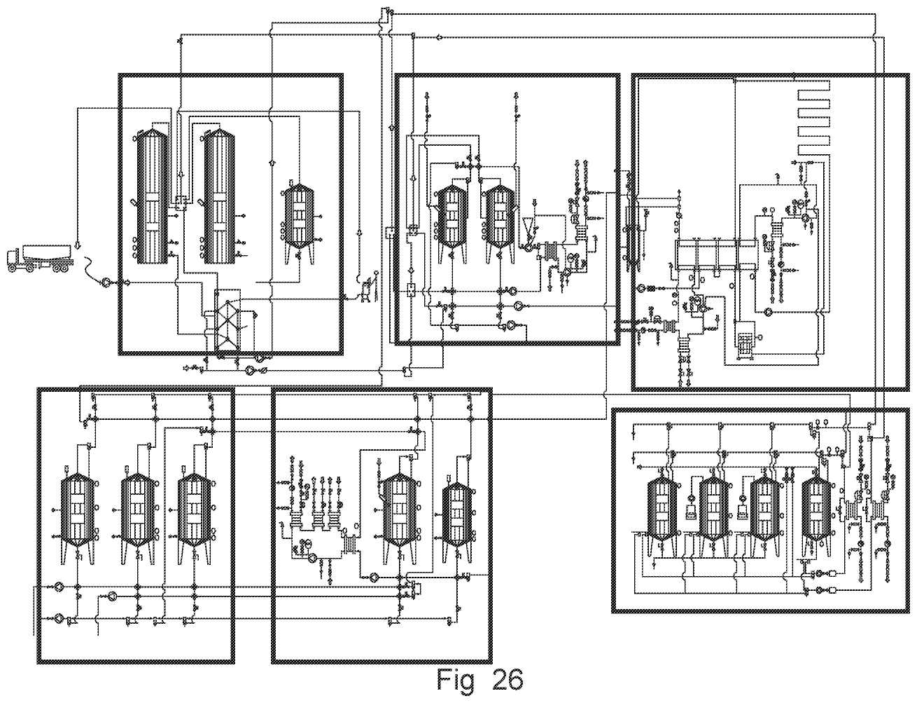

### Identification of a Non-Tank Based Unit is Shown in FIG. 25

After computing the tank based units, the system may compute the connections from the unit's outflows into another unit's inflow. The computation may be based on following the pipes, their flow direction, and the attached control modules. All control modules attached to the pipes on the computed route may be considered as a unit.

### Define Areas

Recognize processing units and common control equipment logical locations.
A single area may be defined with its processing units and common equipment, by proximity on the P&ID diagram e.g., as shown in FIG. 26.

### Define Flow Routes

Autodiscover of routes, to identify flows and the control equipment on the route from external entry points and tanks, into external termination points and tanks. Autodiscover of routes from unit to unit or material flows between various tanks and containers. Specifically:

### External Incoming and Outgoing Routes

External routes are all classified by starting from an external source, or ending with an external destination. The external source or destination are defined when there is neither control nor equipment modules connected to start or end of the route's pipe.
May be computed by starting from external ports, and the respective pipes and control equipment until reaching the unit's main tank. Multiple routes may be computed when an external port connects to multiple units. The unit attached control equipment may be considered as a part of the route.

### Internal Routes

May be computed by starting from outflow ports of a unit, and attaching the respective pipes and control equipment until reaching another unit's main tank. Multiple routes may be computed when an outflow port connects to multiple other units. The unit attached control equipment may be considered as a part of the route.

### Define Shared and Common Equipment

Share equipment are defined as equipment that is part of more than one unit.
Common equipment is defined as equipment that is not part of any unit.
Based on the route's identification and processing units, the system may classify shared control modules. Typically, a control module which is part of one or more than one processing unit, may be considered as shared.

Any outputs herein may be communicated via any suitable data channel or interface to any other software or hardware, and may serve as an input to any suitable physical process and/or may be presented or displayed to human end-users using any suitable electronic device.

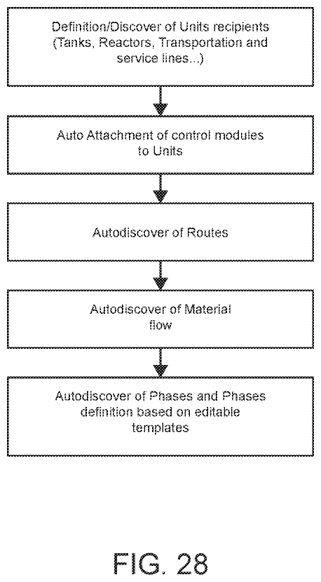

FIG. 28 is a simplified method for facilitating manufacturing in a factory, which includes receiving data (e.g. a P&ID diagram) regarding equipment elements and control modules in the factory; and identifying and providing an output indication of material flow routes that connect at least some of the equipment elements and/or control modules including, for each route, an ordered sequence of equipment elements and/or control modules from a source to a destination and a direction. As shown, the method typically determines attachments of control modules to units in the factory e.g., as described herein, and also typically is configured for storing editable phase templates and for defining phases based on the editable phase templates. This is useful inter alia for route malfunction detection based on operations history of phases and or routes operations and supply and services (e.g., analysis of parallel similar phases).

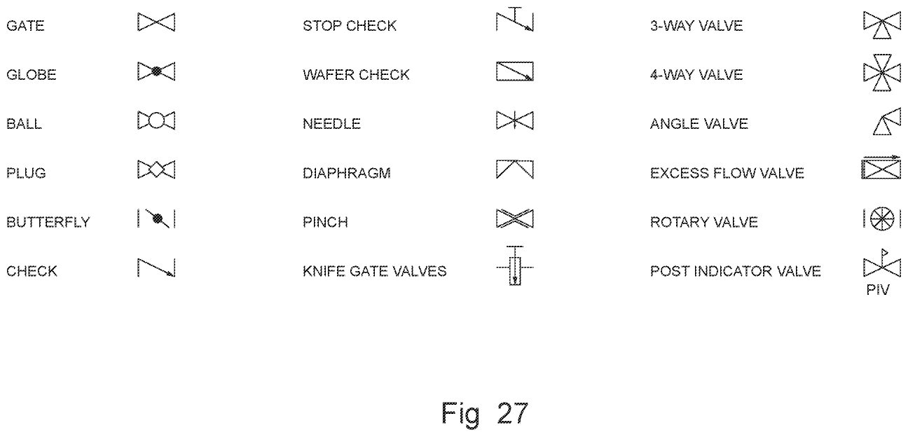

The system herein may define and manage a DB of P&ID shapes, symbols, and images for comparison, and ML models for image recognition patterns. To recognize these shapes, any suitable typically ML-based pattern recognition algorithms may be employed, such as but not limited to Statistical Techniques, Structural Techniques, Template Matching, Neural Networks, Fuzzy logic, or Hybrid Models, or any combination thereof. This DB may comprise different representation of the common P&ID symbols, and their different sizes and drawing variations. Example symbols which may appear in this DB are shown in FIG. 27.

For each symbol different sizes and/or line weights, and/or rotation angles may be defined.

It is appreciated that the information created by the P&ID analysis process described herein may, alternatively, be generated manually. There may be a requirement that certain items of information may be included. All or any subsets of the following items of information (items info1-info8) may be required:
info1—Vector model, which may include all graphical shapes, including lines, dots, polylines, circles, arcs, ellipses, and other; and/or block and shape groups representing P&ID symbols, tanks, and graphical annotations, and/or lines, arcs, freehand lines, representing pipes and flows.
info2—Symbols classification. P&ID shapes, blocks, and symbols may have a classified classification and may be related to P&ID symbols and the system DB.
   Tanks shapes, blocks, and symbols may be classified and related to P&ID symbols and the system DB. Pipelines may be classified.
info3—Modules. Module types (or modules) may be classified into classes such as, say, all or any subset of Equipment module, Control module, Manual Module, or Annotation shape.

A list of modules may be created in the system DB with all or any subset of the following attributes:
functionality: valve, motor, pump, mixer, heater, pressure sensor, etc.
type: for example for valves, is it valve on-off or valve PID, etc.
flow direction: single directional, bi-directional
connection ports and their flow direction: input ports, output ports
titles and annotation texts.

Modules' reference to parent module attachment may be defined, for example, as all attached control modules for each tank equipment module.

It is appreciated that some control modules may be “directional” e.g. as described here: https://store.boschrexroth.com/Hydraulics/Valves/Directional-valves/Directional-here: control-modules?cclcl=en_RO.
info 4 Pipelines. Certain information may be required to be extracted for each pipeline e.g., all or any subset of the following:
Line segments
Joints
Bridges
Flow direction per segment
Classification as external inflow/outflow or internal line
Connectivity to module ports.
Info5—Processing Units. A group of control and equipment modules, including its piping configuration. Processing Unit classification: Tank based Unit, Non-Tank based Unit, CIP Unit.
info6—Flow routes: Configuration of groups of control and equipment modules and their piping which represent a flow of materials from one point into the others. Start and end ports of the flow route. Classification as internal or external and/or as incoming/outgoing.
info7—Area—A group of processing units which are managed within the same logical area.

Logical area: a unit of group of units that are managed as a group because of a similar operational option (example: mixing area, raw material area, assembly machines area) or by geographic installation.
info8—Non-identified shapes e.g., a list or set of shapes, blocks, graphics, texts, which was were not recognized and not classified. By default, these may be classified as annotations.

### Use Cases

It is appreciated that the system herein has wide applicability e.g., as in the flow below, in which all or any subset of whose operations may be performed in any suitable order e.g., as below. The terms “path” and “route” may be interchanged in the present disclosure. Each operation below may be performed in accordance with any embodiment herein.

Operation 210. represent factory's containers, in computer memory/storage, as a graph or tree.

Operation 220. derive, from the graph or tree, route information which typically comprises a set of all possible paths/routes among the factory's containers. Typically, these paths are directional, thus “container A to container B” is considered a different path than “container B to container A”.

Operation 230. For each path in the path-set derived in operation 220, “build all the operating sequences logic for all possible routes in the PLC”. For example, given a pipe with a motor and a valve, then opening sequence may be to open valve then subsequently start motor. Typically, the closing sequence will be to shutdown motor, then close valve.

Typically, computation is done offline, outcome/s may be saved in the PLC, and, in runtime, the HMI may send a trigger to the PLC.

Operation 240. Dynamically e.g., in real time or near-real time, choose a path from among the set of all possible paths generated in operation 20.

Optionally, an operator defines path filtering or ranking criteria, and, responsively, the system server selects a “best” route from among those routes which satisfy those criteria, or presents routes to the operator, ranked by selected criteria.

It is appreciated that alternatively, filtering (or ranking) of less suitable routes from among a large number (e.g., a thousand or more) routes may be automated. Filtering criteria, whether human-selected or automatically activated, may include all or any subset of:
a. Length along the connections between starting point and endpoint of the route
b. Distance between starting point and end-point, “as the crow flies”
c. A requirement that a certain piece of equipment, or certain type of equipment, fall along the route.
d. A requirement that a certain piece of equipment or certain type of equipment, do not fall along the route
e. Ranking according to the number of valves extending along the route
f. Requirement that all pipes along the route be valid for, say, fuel or cleaning fluids.

Operation 250. Understand the connection between the manufacturing process and the physical components, which allow better troubleshooting and optimization of the manufacturing process.

Typically, the system deduces, for each material flow, physical elements related to that flow e.g., pipes, valves, sensors, equipment and/or which physical elements are shared e.g., between plural material flows; and/or which physical units are part of a given working unit, and how does this working unit correlate to a batch or continuous operation that may be ongoing.

Operation 260. Each time operator uses her/his HMI to start a process which causes material to flow from point a to b (process manufacturing), the server typically determines whether there is any overlap between selected routes and/or and blocks material flows. For example, given a junction, a pipe may be identified that belongs to two overlapping (due to at least this junction) routes which are being used for two respective material flows. If, by mistake, an operator were to open both of these in parallel or simultaneously, the material will undesirably be mixed in the shared pipe or container. According to certain embodiments, the system herein blocks this to avoid human error.

To identify overlap, all routes having been identified, the system may determine whether the sets of elements belonging to each pair of routes is disjoint; if so, this pair of routes does not overlap. However, if there is an element which lies along both routes in the pair, this element is shared between the routes, which therefore do overlap. “overlap” may for example be defined as routes 1, 2 used to manufacture product/s (single product, or multiple products), where a path between containers a, b appears both in route 1 and in route 2.

More generally, given process manufacturing facilities which typically heavily rely on transfer of materials between processing units, including for CIP/SIP processes, an efficient method for identifying all relevant routes (system's visibility to all possible routes) is very useful.

Alternatively or in addition, while certain routes (e.g. the shortest route between unit A to unit B) may be used as a routine matter, yet in case of a physical malfunction caused by a faulty element somewhere along the routinely used route, it may be desired to efficiently identify, and use in the interim, pending resolution of the physical malfunction, an alternate route (still leading from A to B), bypassing the faulty element, thus efficiently restoring factory operation.

Such alternate routing is also most useful in CIP (cleaning-in-place) operations, where it may be desired to re-clean the smallest possible segments (sub-routes) that are not clean yet, within a longer, already clean route.

Auto Route discovery (used as a term to describe any embodiment herein) facilitates efficient identification of all such routes, typically relating to the system's stored P&ID as a single-source-of-truth vis a vis piping and/or flow direction and/or valve directions). In a given factory, hundreds of routes or permutations are possible between given two points e.g., a source A and a destination B. The system herein enables the user to filter these by various criteria, and to yield only those routes relevant for a task in hand (for example, ‘only one mixed proof valve within a cluster energized’).

Auto Route discovery may also display to a user locations to which material would flow other than along the route, or beyond the main direction of the route, typically including identification of point/s at which the material flow would be blocked by a closed valve. This facilitates identification of where a cleaning process (CIP) is to be run each time the route is activated, and/or facilitates flagging a plant design error (unintentional material contamination).

Auto Route discovery according to any embodiment herein may provide all or any subset of the following outputs:
a. A set of valid routes interconnecting equipment or modules or units in a factory. Typically each route includes an indication of the route's staritng point and endpoint and/or a sequence of control modules which falls along the route typically beginning from the control module closest to the starting point and ending with the control module closest to the endpoint.
b. Indications of overlap between the routes
c. Indications of all junctions along each route and, for each path extending from the junction other than along the route itself, an indication of at least one control module able to block flow of material flowing along the route into that path aka spillage. Typically, the control module which is indicated is the one closest to the junction, to minimize spillage.
d. Classification of the type of material which flows over each segment of the route e.g. grains vs. liquid vs. gas vs. powder and/or fuel vs. water vs. cleaning fluid etc.
e. Determining which valves (or pumps etc.), depending on each valve's sequence along the route relative to receptacles or other sources of material along the route, are “primary” valves (or pumps) which release or block material flow as opposed to valves whose activation or deactivation does not release or block material flow.

Another use case is route malfunction detection based on operations history of phases and or routes operations and supply and services (e.g. analysis of all or any subset of: steam, cooling liquid, cooling chiller, raw material temperature, pressure in supply line, parallel similar phases) and then, responsively, shutting down the route which has been detected as malfunctioning, optionally identifying an alternative route which is unaffected by the malfunction because the alternative route does not pass through the malfunctioning unit/s of the route, fixing the malfunction e.g. by replacing faulty units, and, typically, reinstating the route whose functioning has been restored, and typically discontinuing use of the alternative route.

It is appreciated that the system herein is but one example. Many variations are possible. For example, to convert a diagram of a factory into a graph model, any suitable method, recursive or otherwise, may be employed, such as but not limited to the following; it is appreciated that in the following, all or any subset of the operations may be performed, in any suitable order e.g. as follows:
Operation a1. Begin with empty graph or tree
Operation a2. Search entire diagram of factory e.g., from top to bottom and left to right, for containers. Each time a non-visited container is recognized, process container recursively as follows:
   Operation i. add a node to graph to represent the non-visited container that has been recognized
   Operation ii. search for pipes entering/exiting the container by scanning the perimeter of the container. For each entering pipe recognized, add to the graph, a directional edge leading into the node. For each exiting pipe recognized, add to the graph, a directional edge leading out of the node.
   Operation iii. Mark container as “visited” on the diagram
   Operation iv. Follow each pipe until a container is recognized; this indicates that the pipe's opposite end has been reached. Unless the container has been visited, process container at opposite end of pipe
Operation a3. When the entire diagram has been scanned, save graph and stop.

Also, given a graph which represents connections e.g. pipes interconnecting containers, and given a system which identifies paths e.g. all possible paths between a given pair of (source and destination) containers and may determine which path portions overlap, it is appreciated that the system may filter out some paths, or, alternatively, may identify “best” paths, using any suitable bestness criteria, including but not limited to shortness of the path (in meters or in number of nodes/containers along the path).

Also, any parameters described herein may be pre-set in the software, or may be configured via an API, in the field, or may be configured by an end-user, via a suitable user interface.

It is appreciated that terminology such as “mandatory”, “required”, “need” and “must” refer to implementation choices made within the context of a particular implementation or application described herewithin for clarity and are not intended to be limiting, since, in an alternative implementation, the same elements might be defined as not mandatory and not required, or might even be eliminated altogether.

Components described herein as software may, alternatively, be implemented wholly or partly in hardware and/or firmware, if desired, using conventional techniques, and vice-versa. Each module or component or processor may be centralized in a single physical location or physical device, or distributed over several physical locations or physical devices.

Included in the scope of the present disclosure, inter alia, are electromagnetic signals in accordance with the description herein. These may carry computer-readable instructions for performing any or all of the operations of any of the methods shown and described herein, in any suitable order, including simultaneous performance of suitable groups of operations as appropriate. Included in the scope of the present disclosure, inter alia, are machine-readable instructions for performing any or all of the operations of any of the methods shown and described herein, in any suitable order; program storage devices readable by machine, tangibly embodying a program of instructions executable by the machine to perform any or all of the operations of any of the methods shown and described herein, in any suitable order i.e. not necessarily as shown, including performing various operations in parallel or concurrently rather than sequentially as shown; a computer program product comprising a computer useable medium having computer readable program code, such as executable code, having embodied therein, and/or including computer readable program code for performing, any or all of the operations of any of the methods shown and described herein, in any suitable order; any technical effects brought about by any or all of the operations of any of the methods shown and described herein, when performed in any suitable order; any suitable apparatus or device or combination of such, programmed to perform, alone or in combination, any or all of the operations of any of the methods shown and described herein, in any suitable order; electronic devices each including at least one processor and/or cooperating input device and/or output device and operative to perform, e.g., in software, any operations shown and described herein; information storage devices or physical records, such as disks or hard drives, causing at least one computer or other device to be configured so as to carry out any or all of the operations of any of the methods shown and described herein, in any suitable order; at least one program pre-stored e.g. in memory or on an information network such as the Internet, before or after being downloaded, which embodies any or all of the operations of any of the methods shown and described herein, in any suitable order, and the method of uploading or downloading such, and a system including server/s and/or client/s for using such; at least one processor configured to perform any combination of the described operations or to execute any combination of the described modules; and hardware which performs any or all of the operations of any of the methods shown and described herein, in any suitable order, either alone or in conjunction with software. Any computer-readable or machine-readable media described herein is intended to include non-transitory computer- or machine-readable media.

Any computations or other forms of analysis described herein may be performed by a suitable computerized method. Any operation or functionality described herein may be wholly or partially computer-implemented e.g., by one or more processors. The invention shown and described herein may include (a) using a computerized method to identify a solution to any of the problems or for any of the objectives described herein, the solution optionally including at least one of a decision, an action, a product, a service, or any other information described herein that impacts, in a positive manner, a problem or objectives described herein; and (b) outputting the solution.

The system may, if desired, be implemented as a network, e.g., web-based system employing software, computers, routers, and telecommunications equipment, as appropriate.

Any suitable deployment may be employed to provide functionalities e.g., software functionalities shown and described herein. For example, a server may store certain applications, for download to clients, which are executed at the client side, the server side serving only as a storehouse. Any or all functionalities e.g., software functionalities shown and described herein, may be deployed in a cloud environment. Clients e.g., mobile communication devices such as smartphones, may be operatively associated with, but external to the cloud.

The scope of the present invention is not limited to structures and functions specifically described herein and is also intended to include devices which have the capacity to yield a structure, or perform a function described herein, such that even though users of the device may not use the capacity, they are, if they so desire, able to modify the device to obtain the structure or function.

Any “if-then” logic described herein is intended to include embodiments in which a processor is programmed to repeatedly determine whether condition x, which is sometimes true and sometimes false, is currently true or false, and to perform y each time x is determined to be true, thereby to yield a processor which performs y at least once, typically on an “if and only if” basis e.g., triggered only by determinations that x is true, and never by determinations that x is false.

Any determination of a state or condition described herein, and/or other data generated herein, may be harnessed for any suitable technical effect. For example, the determination may be transmitted or fed to any suitable hardware, firmware or software module, which is known or which is described herein, to have capabilities to perform a technical operation responsive to the state or condition. The technical operation may, for example, comprise changing the state or condition, or may more generally cause any outcome which is technically advantageous, given the state or condition or data, and/or may prevent at least one outcome which is disadvantageous, given the state or condition or data. Alternatively, or in addition, an alert may be provided to an appropriate human operator, or to an appropriate external system.

Features of the present invention, including operations, which are described in the context of separate embodiments, may also be provided in combination in a single embodiment. For example, a system embodiment is intended to include a corresponding process embodiment, and vice versa. Also, each system embodiment is intended to include a server-centered “view” or client centered “view”, or “view” from any other node of the system, of the entire functionality of the system, computer-readable medium, apparatus, including only those functionalities performed at that server or client or node. Features may also be combined with features known in the art, and particularly, although not limited to, those described in the Background section or in publications mentioned therein.

Conversely, features of the invention, including operations, which are described for brevity in the context of a single embodiment or in a certain order, may be provided separately or in any suitable sub-combination, including with features known in the art (particularly although not limited to those described in the Background section or in publications mentioned therein) or in a different order. “e.g.” is used herein in the sense of a specific example which is not intended to be limiting. Each method may comprise all or any subset of the operations illustrated or described, suitably ordered e.g., as illustrated or described herein.

Devices, apparatus or systems shown coupled in any of the drawings may in fact be integrated into a single platform in certain embodiments, or may be coupled via any appropriate wired or wireless coupling, such as but not limited to optical fiber, Ethernet, Wireless LAN, HomePNA, power line communication, cell phone, Smart Phone (e.g. iPhone), Tablet, Laptop, PDA, Blackberry GPRS, Satellite including GPS, or other mobile delivery. It is appreciated that in the description and drawings shown and described herein, functionalities described or illustrated as systems and sub-units thereof, can also be provided as methods and operations therewithin, and functionalities described or illustrated as methods and operations therewithin can also be provided as systems and sub-units thereof. The scale used to illustrate various elements in the drawings is merely exemplary and/or appropriate for clarity of presentation, and is not intended to be limiting.

Any suitable communication may be employed between separate units herein e.g., wired data communication and/or in short-range radio communication with sensors such as cameras e.g. via Wifi, Bluetooth or Zigbee.

It is appreciated that implementation via a cellular app as described herein is but an example, and, instead, embodiments of the present invention may be implemented, say, as a smartphone SDK, as a hardware component, as an STK application, or as suitable combinations of any of the above.

Any processing functionality illustrated (or described herein) may be executed by any device having a processor, such as but not limited to a mobile telephone, set-top-box, TV, remote desktop computer, game console, tablet, mobile e.g. laptop or other computer terminal, embedded remote unit, which may either be networked itself (may itself be a node in a conventional communication network e.g.) or may be conventionally tethered to a networked device (to a device which is a node in a conventional communication network or is tethered directly or indirectly/ultimately to such a node).

Any operation or characteristic described herein may be performed by another actor outside the scope of the patent application, and the description is intended to include apparatus, whether hardware, firmware, or software, which is configured to perform, enable, or facilitate that operation, or to enable, facilitate, or provide that characteristic.

The terms processor or controller or module or logic as used herein are intended to include hardware such as computer microprocessors or hardware processors, which typically have digital memory and processing capacity, such as those available from, say Intel and Advanced Micro Devices (AMD). Any operation or functionality or computation or logic described herein may be implemented entirely or in any part on any suitable circuitry including any such computer microprocessor/s as well as in firmware or in hardware or any combination thereof.

It is appreciated that elements illustrated in more than one drawings, and/or elements in the written description, may still be combined into a single embodiment, except if otherwise specifically clarified herewithin. Any of the systems shown and described herein may be used to implement or may be combined with, any of the operations or methods shown and described herein.

It is appreciated that any features, properties, logic, modules, blocks, operations, or functionalities described herein which are, for clarity, described in the context of separate embodiments, may also be provided in combination in a single embodiment, except where the specification or general knowledge specifically indicates that certain teachings are mutually contradictory, and cannot be combined. Any of the systems shown and described herein may be used to implement or may be combined with, any of the operations or methods shown and described herein.

Conversely, any modules, blocks, operations or functionalities described herein, which are, for brevity, described in the context of a single embodiment, may also be provided separately or in any suitable sub-combination, including with features known in the art. Each element, e.g., operation described herein, may have all characteristics and attributes described or illustrated herein, or, according to other embodiments, may have any subset of the characteristics or attributes described herein.

References herein to “said (or the) element x” having certain (e.g., functional or relational) limitations/characteristics, are not intended to imply that a single instance of element x is necessarily characterized by all the limitations/characteristics. Instead, “said (or the) element x” having certain (e.g. functional or relational) limitations/characteristics is intended to include both (a) an embodiment in which a single instance of element x is characterized by all of the limitations/characteristics and (b) embodiments in which plural instances of element x are provided, and each of the limitations/characteristics is satisfied by at least one instance of element x, but no single instance of element x satisfies all limitations/characteristics. For example, each time L limitations/characteristics are ascribed to “said” or “the” element X in the specification or claims (e.g. to “said processor” or “the processor”), this is intended to include an embodiment in which L instances of element X are provided, which respectively satisfy the L limitations/characteristics, each of the L instances of element X satisfying an individual one of the L limitations/characteristics. The plural instances of element x need not be identical. For example, if element x is a hardware processor, there may be different instances of x, each programmed for different functions and/or having different hardware configurations (e.g., there may be 3 instances of x: two Intel processors of different models, and one AMD processor).

1.-29. (canceled)

30. A method for facilitating manufacturing in a factory, the method comprising:
receiving a piping and instrumentation diagram (P&ID) of equipment elements and of control modules in the factory;
using a hardware processor to perform the following:
(I) perform image recognition on the received P&ID, comprising:
a. recognizing at least one symbol or shape, associated with elements of the P&ID; and
b. classify the at least one symbol or shape;
(II) identify, based at least on the image recognition, material flow routes that connect at least some of the equipment elements and/or control modules, wherein the identification includes, for each material flow route;
a. an ordered sequence of equipment elements and/or control modules from a source to a destination; and
b. a direction associated with the route; and
(III) provide an output indication of the material flow routes.

31. The method of claim 30, wherein all routes from a given source to a given destination are identified.

32. The method of claim 30, wherein the method identifies only routes whose direction is valid, taking into account all directional control modules, such as motors, along the routes.

33. The method of claim 30, wherein, upon request, the method filters out a subset of routes from the given source to the given destination which do not comply with a user-provided route filtering criterion.

34. The method of claim 33, wherein the subset of routes comprises all routes which pass through a given factory equipment element and/or given a control module, thereby facilitating re-routing each time a given factory equipment element, line, and/or given control module is malfunctioning, thereby facilitating a reduced down-time.

35. The method of claim 30, further comprising:
(IV) identifying all control modules along a given route that need to be opened in order to ensure that material flows from said source element to said destination element via said given route.

36. The method of claim 30, further comprising:
(V) identifying all control modules that need to be closed in order to ensure that material does not flow via any route other than said route.

37. The method of claim 30, further comprising:
(VI) manufacturing of goods in the factory typically using a formula or recipe, the manufacturing including combining materials wherein material flow routes to combine the materials are selected based on said output indication.

38. The method of claim 30, wherein the P&ID diagram is converted to vector format.

39. The method of claim 30, further comprising:
(VII) identify at least two overlapping routes of the material flow routes
(VIII) determine that the at least two overlapping are incapable of operating simultaneously; and
(IX) responsive to detecting a command that plural routes of the at least two overlapping routes should operate simultaneously, perform at least one of the following:
a. closing off material flow to one or both routes of the at plural routes; and
b. providing an alert indication.

40. The method of claim 30,
wherein the image recognition comprises recognizing pipes in the P&ID diagram,
and wherein a flow direction of each pipe is defined based on the elements of the P&ID.

41. The method of claim 30, wherein the image recognition utilizes machine learning models.

42. The method of claim 30, wherein tanks pipes in the P&ID diagram are defined as tanks.

43. The method of claim 30, wherein process unit components are defined.

44. The method of claim 43, wherein the process unit components which are defined include at least one inner control module of at least one tank.

45. The method of claim 43, wherein the process unit components which are defined include at least one connection port.

46. The method of claim 43, wherein the process unit components which are defined include external inflows and outflows.

47. The method of claim 43, wherein the process unit components which are defined include at least one of the following:
at least process unit; and
at least one area.

48. The method of claim 43, wherein the process unit components which are defined include at least one flow route.

49. The method of claim 30, further comprising:
(X) generating, based on the image recognition and the identification of the material flow routes, a database of interconnected equipment and control modules, with functional relationships.

50. The method of claim 43, further comprising:
(XI) defining at least one control module as a common or shared control module.

51. The method of claim 30, further comprising:
(XII) storing editable phase templates and wherein phases are defined based on the editable phase templates.

52. The method of claim 30, wherein said control modules include at least one of the following:
(a) at least one sensor sensing a state of at least one of the equipment elements and/or control modules; and
(b) at least one actuator such as a motor/engine or valve.

53. The method of claim 30, further comprising:
(XIII) generating controller code, which performs an implementation protocol to activate and/or deactivate elements of route segments along a selected material flow route, thereby facilitating movement of material, from a first module in the factory to a second module in the factory, along the selected material flow route.

54. The method of claim 30, wherein said control modules are controlled by respective PLC controllers.

55. The method of claim 30, wherein said equipment elements include at least one tank.

56. The method of claim 30, wherein at least some control modules are attached to at least one unit, e.g., to at least one of said equipment elements.

57. A hardware processor configured to perform the method of any claim 30.

58. A computer program product, comprising a non-transitory tangible computer readable medium having computer readable program code embodied therein, said computer readable program code adapted to be executed by processing hardware to perform the method of claim 30.
